(19) United States
(12) Patent Application Publication
(10) Pub. No.: US 2024/0128275 A1
(43) Pub. Date: Apr. 18, 2024

(54) DISPLAY APPARATUS

(71) Applicant: Samsung Display Co., Ltd., Yongin-si (KR)

(72) Inventors: Deokyoung Choi, Yongin-si (KR); Seongsik Ahn, Yongin-si (KR); Sunho Kang, Yongin-si (KR); Wonjang Ki, Yongin-si (KR); Namjin Kim, Yongin-si (KR); Mikyung Kim, Yongin-si (KR); Yeonju Seo, Yongin-si (KR)

(21) Appl. No.: 18/221,774

(22) Filed: Jul. 13, 2023

(30) Foreign Application Priority Data
Oct. 12, 2022 (KR) 10-2022-0130921

(51) Int. Cl. H01L 27/12; G09G 3/3233

(52) U.S. Cl. CPC H01L 27/124; G09G 3/3233; G09G 2300/0842

(57) ABSTRACT

A display apparatus including: a substrate; an interlayer insulating layer on the substrate; a first organic insulating layer on the interlayer insulating layer; a first connection wiring configured to transmit a driving voltage to the plurality of pixels on the interlayer insulating layer and having at least a portion extending in a first direction; a driving unit configured to supply the driving voltage to the plurality of pixels through the first connection wiring; and a feedback wiring configured to transmit a feedback voltage between the plurality of pixels and the first connection wiring to the driving unit on the interlayer insulating layer and being in direct contact with a top surface of the interlayer insulating layer in at least a portion of the sub area, wherein the driving unit is configured to adjust the driving voltage, based on the feedback voltage.

### CROSS-REFERENCE TO RELATED APPLICATION

The present application claims priority to and the benefit of Korean Patent Application No. 10-2022-0130921, filed on Oct. 12, 2022, in the Korean Intellectual Property Office, the entire disclosure of which is incorporated herein by reference.

### BACKGROUND

### 1. Field

Aspects of one or more embodiments relate to a display apparatus.

### 2. Description of the Related Art

Display apparatuses are apparatuses that receive information about an image and display the image. A pixel included in a display apparatus may emit light by receiving a driving voltage. Thus, the supply of a driving voltage having a relatively uniform magnitude may be desired.

Thus, a driving unit may sense the magnitude of the driving voltage by using an additional wiring for monitoring the driving voltage. However, when a problem occurs in an additional wiring for monitoring the driving voltage, the magnitude of the driving voltage cannot be accurately sensed.

The above information disclosed in this Background section is only for enhancement of understanding of the background and therefore the information discussed in this Background section does not necessarily constitute prior art.

### SUMMARY

Aspects of one or more embodiments relate to a display apparatus, and for example, to a display apparatus in which accurate monitoring of a driving voltage applied to a display element may be performed.

One or more embodiments include a display apparatus in which accurate monitoring of a driving voltage applied to a display element may be performed. However, this objective is just an example, and the scope of the present disclosure is not limited thereby.

Additional aspects will be set forth in part in the description which follows and, in part, will be apparent from the description, or may be learned by practice of the presented embodiments of the disclosure.

According to one or more embodiments, a display apparatus includes a substrate including a main area in which a plurality of pixels are arranged, a bending area bent around a bending axis from an outside of the main area, and a sub area located on an opposite side to the main area with respect to the bending area, an interlayer insulating layer located on the substrate, a first organic insulating layer located on the interlayer insulating layer, a first connection wiring configured to transmit a driving voltage to the plurality of pixels on the interlayer insulating layer and having at least a portion extending in a first direction, a driving unit configured to supply the driving voltage to the plurality of pixels through the first connection wiring, and a feedback wiring configured to transmit a feedback voltage between the plurality of pixels and the first connection wiring to the driving unit on the interlayer insulating layer and being in direct contact with a top surface of the interlayer insulating layer in at least a portion of the sub area, wherein the driving unit is configured to adjust the driving voltage, based on the feedback voltage.

According to some embodiments, the feedback wiring may include a first sub feedback wiring being in direct contact with a top surface of the interlayer insulating layer in at least a portion of the sub area, and a second sub feedback wiring being in direct contact with a top surface of the first sub feedback wiring.

According to some embodiments, the first connection wiring may include a (1-1)-th sub connection wiring having a same layered structure as the first sub feedback wiring on the interlayer insulating layer and including the same material as that of the first sub feedback wiring, and a (1-2)-th sub connection wiring being in direct contact with a top surface of the (1-1)-th sub connection wiring, having the same layered structure as that of the second sub feedback wiring and including the same material as that of the second sub feedback wiring.

According to some embodiments, the display apparatus may further include a first conductive layer arranged between the interlayer insulating layer and the first organic insulating layer, and a second conductive layer arranged on the first organic insulating layer.

According to some embodiments, the first sub feedback wiring may have a same layered structure as that of the first conductive layer and includes a same material as that of the first conductive layer, and the second sub feedback wiring may have a same layered structure as that of the second conductive layer and includes a same material as that of the second conductive layer.

According to some embodiments, the display apparatus may further include a second connection wiring configured to transmit a common voltage to the main area on the interlayer insulating layer, at least a portion of the second connection wiring being spaced apart from the first connection wiring in a second direction crossing the first direction by a first length when viewed in a direction perpendicular to the substrate.

According to some embodiments, the feedback wiring may be arranged between the first connection wiring and the second connection wiring when viewed in a direction perpendicular to the substrate.

According to some embodiments, the feedback wiring may include a first portion having a single layer structure in the sub area, and a second portion extending from the first portion in an opposite direction of the main area, having a multi-layer structure and connected to the driving unit.

According to some embodiments, the second portion may extend in the first direction by a second length when viewed in a direction perpendicular to the substrate, and the second length may be greater than the first length.

According to some embodiments, the second portion may extend in the first direction by a second length when viewed in a direction perpendicular to the substrate, and the second length may be at least 200 μm and not more than 300 μm.

According to some embodiments, the second portion may include a first sub feedback wiring being in direct contact with the top surface of the interlayer insulating layer, and a second sub feedback wiring being in direct contact with the top surface of the first sub feedback wiring.

According to some embodiments, the second connection wiring may include a (2-1)-th sub connection wiring having the same layered structure as that of the first sub feedback wiring on the interlayer insulating layer and including the same material as that of the first sub feedback wiring, and a (2-2)-th sub connection wiring being in direct with a top surface of the (2-1)-th sub connection wiring, having the same layered structure as that of the second sub feedback wiring, and including the same material as that of the second sub feedback wiring.

According to some embodiments, the first organic insulating layer may be arranged under the first portion, and a top surface of the interlayer insulating layer may be in direct contact with a bottom surface of the second portion.

According to some embodiments, the first connection wiring may be divided into a plurality of connection wirings in the bending area.

According to some embodiments, the second connection wiring may be divided into a plurality of connection wirings in the bending area.

According to some embodiments, the display apparatus may further include a second organic insulating layer arranged on the first connection wiring and the feedback wiring in the sub area.

According to some embodiments, the interlayer insulating layer may include an opening corresponding to the bending area and exposing the substrate.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a plan view schematically illustrating a portion of a display apparatus according to some embodiments;

FIG. 2 is a side view schematically illustrating a portion of the display apparatus of FIG. 1 according to some embodiments;

FIG. 3 is an equivalent circuit diagram of one pixel of the display apparatus of FIG. 1 according to some embodiments;

FIG. 4 is a side view schematically illustrating a portion of the display apparatus of FIG. 1 according to some embodiments;

FIG. 5 is a plan view schematically illustrating region A of FIG. 1 according to some embodiments;

FIG. 6 is a schematic cross-sectional view of the display apparatus taken along the line I-I′ of FIG. 5, centered on a feedback wiring according to some embodiments;

FIG. 7 is a schematic cross-sectional view of the display apparatus taken along the line II-II′ of FIG. 5, centered on a feedback wiring according to some embodiments;

FIG. 8 is a schematic cross-sectional view schematically illustrating a portion of a display apparatus according to a comparative example;

FIG. 9 is a schematic plan view schematically illustrating a portion of a display apparatus according to a comparative example; and

FIG. 10 is a schematic cross-sectional view of the display apparatus taken along the line III-III′ of FIG. 5, centered on an inorganic layer.

### DETAILED DESCRIPTION

Reference will now be made in more detail to aspects of some embodiments, which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Because various modifications and various embodiments of the present disclosure are possible, specific embodiments are illustrated in the drawings and described in more detail in the detailed description. Effects and features of the present disclosure, and a method of achieving them will be apparent with reference to embodiments described below in more detail in conjunction with the drawings. However, the present disclosure is not limited to the embodiments disclosed herein, but may be implemented in a variety of forms.

Hereinafter, embodiments of the present disclosure will be described in more detail with reference to the accompanying drawings, and same reference numerals are used for same or corresponding components when describing embodiments of the present disclosure, and a redundant description thereof is omitted.

In the following embodiments, when various components such as a layer, a region, a plate, and the like are “on” other components, this is not only when the component is “directly on” other components, but also when other components are interposed therebetween. In the drawings, for convenience of explanation, the sizes of components may be exaggerated or reduced. For example, because the size and thickness of each component shown in the drawings are arbitrarily indicated for convenience of explanation, the present disclosure is not necessarily limited to the illustration.

In the following embodiments, the x-axis, the y-axis, and the z-axis are not limited to three axes on an orthogonal coordinate system, and may be interpreted in a broad sense including the same. For example, the x-axis, the y-axis, and the z-axis may be perpendicular to each other, but may refer to different directions that are not orthogonal to each other.

Hereinafter, a display apparatus according to some embodiments of the present disclosure will be described in more detail based on the above-described contents.

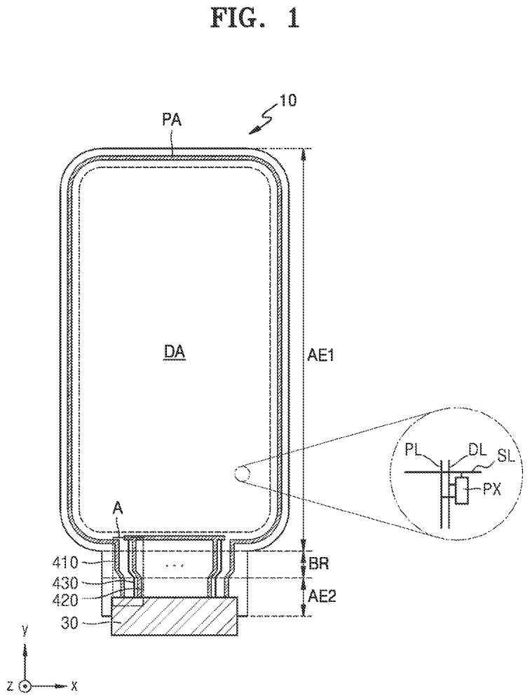

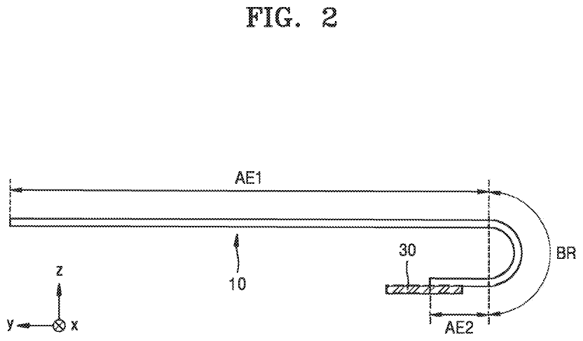

FIG. 1 is a plan view schematically illustrating a portion of a display apparatus according to some embodiments of the present disclosure, and FIG. 2 is a side view schematically illustrating a portion of the display apparatus of FIG. 1.

As shown in FIGS. 1 and 2, the display apparatus according to some embodiments may include a display panel 10. The display apparatus may be a display apparatus that includes the display panel 10. For example, the display apparatus may be one of various products such as smartphones, tablets, laptops, televisions, advertising boards, and the like.

The display panel 10 may include a display area DA and a peripheral area PA outside (e.g., in a periphery or outside a footprint of) the display area DA. The display area DA that is a portion or area at which images are displayed, and a plurality of pixels PX may be arranged in the display area DA. When viewed in a direction substantially perpendicular or normal with respect to the display panel 10 (e.g., in a plan view), the display area DA may have various shapes such as a circular shape, an oval shape, a polygonal shape, and a specific figure shape. In FIG. 1, the display area DA has a substantially rectangular shape with rounded corners.

The peripheral area PA may be outside the display area DA. A width (in an x-axis direction) of a portion of the peripheral area PA may be less than a width (in the x-axis direction) of the display area DA. Through this structure, a portion of the peripheral area PA may be relatively easily bent as described below.

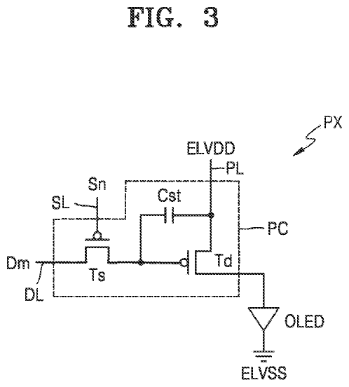

The display panel 10 includes a substrate 100 (see FIG. 3), which will be described in more detail later, and thus the substrate 100 to be described in more detail later may have the display area DA and the peripheral area PA as described above. For convenience of description and illustration, the substrate 100 may be described as having the display area DA and the peripheral area PA.

The display panel 10 may also have a main area AE1, a bending area BR outside the main area AE1, and a sub area AE2 positioned opposite to the main area AE1 around the bending area BR. In the bending area BR, the display panel 10 may be bent, as shown in FIG. 2, so that a part of the sub area AE2 overlaps the main area AE1 when viewed in a z-axis direction (e.g., in a plan view). Of course, embodiments of the present disclosure are not limited to the bent display apparatus, and may also be applied to an unbent display apparatus. The sub area AE2 may be a non-display area, as will be described later, or may include a non-display area. The display panel 10 may be bent in the bending area BR so that, even if the display apparatus is viewed in the front side (in a −z-direction), the non-display area may not be visible, or the visible area may be minimized.

Of course, the display panel 10 includes the substrate 100. Thus, the substrate 100 may also have the main area AE1, the bending area BR, and the sub area AE2, as described above. Hereinafter, for convenience, the substrate 100 may be described to have the main area AE1, the bending area BR, and the sub area AE2.

A driving unit (or driver) 30 may be located in the sub area AE2 of the display panel 10. The driving unit 30 may include an integrated circuit for driving the display panel 10. The integrated circuit may be a data driving integrated circuit for generating a data signal. However, embodiments of the present disclosure are not limited thereto.

The driving unit 30 may be mounted in the sub area AE2 of the display panel 10. The driving unit 30 may be mounted on the same surface as a display surface of the display area DA. However, as described above, as the display panel 10 is bent in the bending area BR, the driving unit 30 may be located on a rear surface of the main area AE1.

Hereinafter, an organic light-emitting display apparatus as a display apparatus according to some embodiments of the present disclosure is described as an example, but the display apparatus of the present disclosure is not limited thereto. According to some embodiments, the display apparatus according to the present disclosure may be a display apparatus such as an inorganic light-emitting display or an inorganic electroluminescent (EL) display apparatus, or a quantum dot light-emitting display apparatus. For example, a light emitting layer of a display element of the display apparatus may include an organic material or an inorganic material. Also, the display apparatus may include a light emitting layer and a quantum dot layer located on a path of light emitted from the light emitting layer.

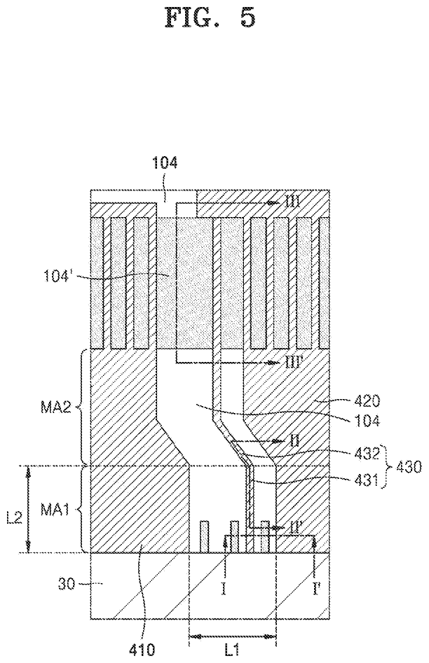

The display area DA that is a portion at which images are displayed, and a plurality of pixels PX may be arranged in the display area DA. Each of the plurality of pixels PX may include a display element such as an organic light emitting diode. Each pixel PX may emit red, green or blue light, for example. The pixel PX may be connected to a pixel circuit including a thin film transistor (TFT), a storage capacitor, and the like. The pixel circuit may be connected to a scan line SL for transmitting a scan signal, a data line DL that crosses the scan line SL and transmits a data signal, and a driving voltage line PL for supplying a driving voltage. The scan line SL may extend in an x-direction, and the data line DL and the driving voltage line PL may extend in a y-direction. The driving voltage line PL may be connected to a first connection wiring (420 of FIG. 5) to be described in more detail later.

The pixel PX may emit light having luminescence corresponding to an electrical signal from the pixel circuit electrically connected to the pixel PX. The display area DA may display a certain image through light emitted from the pixel PX. For reference, the pixel PX may be defined as a light emitting area in which light of one color of red, green and blue is emitted, as described above.

The plurality of pixels PX may be electrically connected to outer circuits arranged in the peripheral area PA. A scan driving circuit, an emission control driving circuit, a terminal, a driving power supply wiring, an electrode power supply wiring, and the like may be located in the peripheral area PA. The scan driving circuit may provide a scan signal to the pixel PX through the scan line. The emission control driving circuit may provide an emission control signal to the pixel PX through the emission control line. The terminal located in the peripheral area PA may not be covered by an insulating layer but may be exposed and may be electrically connected to the driving unit 30. The terminal of the driving unit 30 may be electrically connected to the terminal of the display panel 10.

As shown in FIG. 1, the peripheral area PA of the substrate 100 may surround the display area DA. The peripheral area PA may be an area in which the pixels PX are not arranged, and a first connection wiring 420 and a second connection wiring 410 for supplying power for driving a light emitting element may be arranged in the peripheral area PA. The first connection wiring 420 may be a driving voltage ELVDD wiring, and the second connection wiring 410 may be a common voltage ELVSS wiring. In an example, the first connection wiring 420 may be arranged between one edge of the display area DA and the driving unit 30, and the second connection wiring 410 may be located to correspond to another edge of the display area DA. In an example, the second connection wiring 410 may surround the other edges of the display area DA excluding one edge of the display area DA in which the first connection wiring 420 is located.

FIG. 1 may be understood as a plan view illustrating the state of the substrate 100 during the manufacturing process of the display apparatus. In an electronic apparatus such as a smartphone including the final display apparatus or the display apparatus, the bending area BR may be bent, as shown in FIG. 2, in order to minimize or reduce the area of the peripheral area PA recognized or perceived by a user.

FIG. 3 is an equivalent circuit diagram of one pixel of the display apparatus of FIG. 1.

As illustrated in FIG. 3, each pixel PX may include a pixel circuit PC connected to the scan line SL and the data line DL, and an organic light emitting diode OLED connected to the pixel circuit PC.

The pixel circuit PC may include a driving thin film transistor Td, a switching thin film transistor Ts, and a storage capacitor Cst. The switching thin film transistor Ts may be connected to the scan line SL and the data line DL and may transmit a data signal Dm inputted through the data line DL in response to a scan signal Sn inputted through the scan line SL to the driving thin film transistor Td.

The storage capacitor Cst may be connected to the switching thin film transistor Ts and the driving voltage line PL and may store a voltage that corresponds to a difference between a voltage transmitted from the switching thin film transistor Ts and the driving voltage ELVDD supplied to the driving voltage line PL.

The driving thin film transistor Td may be connected to the driving voltage line PL and the storage capacitor Cst and may control a driving current that flows through the organic light emitting diode OLED from the driving voltage line PL in response to a value of the voltage stored in the storage capacitor Cst. The organic light emitting diode OLED may emit light having certain luminescence by the driving current.

FIG. 3 illustrates a case where the pixel circuit PC includes two thin film transistors and one storage capacitor. However, embodiments according to the present disclosure are not limited thereto. The pixel circuit PC may also include two or more storage capacitors.

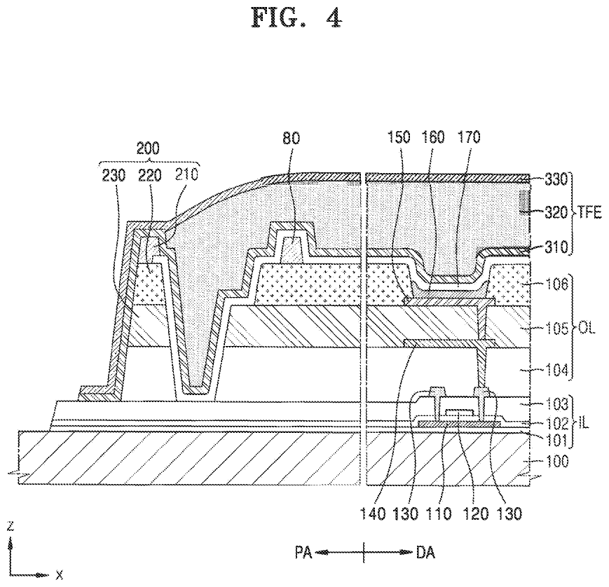

FIG. 4 is a side view schematically illustrating a portion of the display apparatus of FIG. 1.

The substrate 100 may include the display area DA and the peripheral area PA outside the display area DA, as described above. Also, the substrate 100 may include a main area AE1 in which a plurality of pixels are arranged, a bending area BR bent around a bending axis from an outside of the main area AE1, and a sub area AE2 located opposite to the main area AE1 based on the bending area BR.

The substrate 100 may include various materials having flexible or bendable characteristics. For example, the substrate 100 may include glass, metal or a polymer resin. Also, the substrate 100 may include a polymer resin such as polyethersulphone, polyacrylate, polyetherimide, polyethylene naphthalate, polyethylene terephthalate, polyphenylene sulfide, polyarylate, polyimide, polycarbonate or cellulose acetate propionate. The substrate 100 may be variously modified like having a multi-layered structure including two layers including the polymer resin, and a barrier layer including an inorganic material such as silicon oxide, silicon nitride, silicon oxynitride, etc. interposed between the two layers.

A buffer layer 101 may be located on the substrate 100. The buffer layer 101 may prevent diffusion of impurity ions, prevent or reduce penetration of moisture, contaminants, or external air, and serve as a barrier layer and/or a blocking layer for planarizing a surface. The buffer layer 101 may include silicon oxide, silicon nitride or silicon oxynitride. In addition, the buffer layer 101 may adjust the supply speed of heat during a crystallization process for forming the semiconductor layer 110 so that the semiconductor layer 110 may be relatively uniformly crystallized.

The semiconductor layer 110 may be located on the buffer layer 101. The semiconductor layer 110 may be formed of polysilicon, and may include a channel region that is not doped with impurities, and a source region and a drain region that are formed by doping impurities on both sides of the channel region. Here, the impurities may vary according to the type of a thin film transistor and may be N-type impurities or P-type impurities.

A gate insulating layer 102 may be located on the semiconductor layer 110. The gate insulation layer 102 may be configured to secure insulation between the semiconductor layer 110 and the gate layer 120. The gate insulating layer 102 may include an inorganic material such as silicon oxide, silicon nitride and/or silicon oxynitride and may be between the semiconductor layer 110 and the gate layer 120. In addition, the gate insulating layer 102 may have a shape corresponding to the entire surface of the substrate 100 and may have a structure in which contact holes are formed in a preset portion of the gate insulating layer 102. In this way, an insulating layer including an inorganic material may be formed through chemical vapor deposition (CVD) or atomic layer deposition (ALD). This also applies to the following embodiments and variations thereof.

A gate layer 120 may be located on the gate insulating layer 102. The gate layer 120 may be located at a position where the gate layer 120 overlaps the semiconductor layer 110 in a vertical direction, and may include at least one metal such as molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tungsten (W), and copper (Cu). A detailed description of the gate layer 120 is omitted below.

An interlayer insulating layer 103 may be located on the gate layer 120. The interlayer insulating layer 103 may cover the gate layer 120. The interlayer insulating layer 103 may include an inorganic material. For example, the interlayer insulating layer 103 may include metal oxide or metal nitride, and specifically, the inorganic material may include silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), or zinc oxide (ZrO₂). The interlayer insulating film 103 may, in some embodiments, include a dual structure of SiOx/SiNy or SiNx/SiOy.

The first conductive layer 130 may be located on the interlayer insulating layer 103. The first conductive layer 130 may serve as an electrode connected to a source/drain region of the semiconductor layer through a through hole included in the interlayer insulating layer 103. In particular, the first conductive layer 130 may be located in the main area AE1. The first conductive layer 130 may be located between the interlayer insulating layer 103 and the first organic insulating layer 104 to be described later.

The first conductive layer 130 may include one or more metals selected from the group consisting of Al, Pt, Pd, Ag, Mg, Au, Ni, Nd, Ir, Cr, Li, Ca, Mo, Ti, W, and Cu. For example, the first conductive layer 130 may include a Ti layer, an Al layer and/or a Cu layer.

A first organic insulating layer 104 may be located on the first conductive layer 130. The first organic insulating layer 104 may cover an upper portion of the first conductive layer 130 and may have a substantially flat upper surface, thereby being an organic insulating layer serving as a planarization layer. The first organic insulating layer 104 may include an organic material such as benzocyclobutene (BCB) hexamethyldisiloxane (HMDSO). The first organic insulating layer 104 may be variously modified like having a single layer or multi-layer structure.

The second conductive layer 140 may be located on the first organic insulating layer 104. The second conductive layer 140 may serve as an electrode connected to a source/drain region of the semiconductor layer through a through hole included in the first organic insulating layer 104.

The second conductive layer 140 may include one or more metals selected from the group consisting of Al, Pt, Pd, Ag, Mg, Au, Ni, Nd, Ir, Cr, Li, Ca, Mo, Ti, W, and Cu. For example, the second conductive layer 140 may include a Ti layer, an Al layer and/or a Cu layer.

The second organic insulating layer 105 may be located on the second conductive layer 140. The second organic insulating layer 105 may cover an upper portion of the second conductive layer 140 and may have a substantially flat upper surface, thereby being an organic insulating layer serving as a planarization layer. The second organic insulating layer 105 may include an organic material such as BCB or HMDSO. The second organic insulating layer 105 may be variously modified like having a single layer or multi-layer structure.

In addition, according to some embodiments, an additional conductive layer and an additional insulating layer may be interposed between the first conductive layer 130 and the pixel electrode 150, and may be applied to various embodiments. In this case, the additional conductive layer may include the same material as the above-described conductive layer and may have the same layered structure. The additional insulating layer may include the same material as the above-described organic insulating layer and may have the same layered structure.

The pixel electrode 150 may be located on the second organic insulating layer 105. The pixel electrode 150 may be connected to the second conductive layer 140 through a contact hole formed in the second organic insulating layer 105. A display element may be located on the pixel electrode 150. The organic light emitting device OLED may be used as the display element. That is, the organic light emitting device OLED may be interposed on the pixel electrode 150, for example. The pixel electrode 150 may include a light-transmitting conductive layer formed of a light-transmitting conductive oxide such as ITO, In₂O₃ or IZO, and a reflective layer formed of metal such as Al or Ag. For example, the pixel electrode 150 may have a three-layer structure of ITO/Ag/ITO.

A pixel-defining layer 106 may be located on the second organic insulating layer 105 and may be arranged to cover edges of the pixel electrode 150. That is, the pixel-defining layer 106 may cover edges of the pixel electrode 150. The pixel-defining layer 106 may have an opening corresponding to a pixel, and the opening may be formed so that at least a center part of the pixel electrode 150 may be exposed.

The pixel-defining layer 106 may include an organic material such as polyimide or HMDSO. In addition, a spacer 80 may be located on the pixel-defining layer 106. The spacer 80 may be located in the peripheral area PA but may be located in the display area DA. The spacer 80 may prevent the organic light emitting diode OLED from being damaged by sagging of a mask in a manufacturing process using the mask. The spacer 80 may include an organic insulating material and may have a single layer or multi-layer structure.

For reference, in the present specification, the organic material layer OL may include a first organic insulating layer 104, a second organic insulating layer 105, and a pixel-defining layer 106. In addition, in the present specification, an inorganic layer IL may include a buffer layer 101, a gate insulating layer 102, and an interlayer insulating layer 103.

An intermediate layer 160 and an opposite electrode 170 may be located on the opening. The intermediate layer 160 may include a small molecular weight material or a polymer material. When the intermediate layer 160 includes a low molecular weight material, the intermediate layer 160 may include a hole injection layer (HIL), a hole transport layer (HTL), an emission layer (EML), an electron transport layer (ETL), and/or an electron injection layer (EIL). When the intermediate layer 160 includes a polymer material, the intermediate layer 160 may have a structure including the HTL and the EML. The opposite electrode 170 may include a light-transmitting conductive layer formed of a light-transmitting conductive oxide such as ITO, In₂O₃ or IZO. The pixel electrode 150 may be used as an anode, and the opposite electrode 170 may be used as a cathode. Of course, the polarity of the electrode may be applied in an opposite manner.

The structure of the intermediate layer 160 is not limited to the above description, and the intermediate layer 160 may have various structures. For example, at least one of layers for forming the intermediate layer 160 may be integrally formed, like the opposite electrode 170. According to some embodiments, the intermediate layer 160 may include a patterned layer to correspond to each of the plurality of pixel electrodes 150.

The opposite electrode 170 may be located on an upper portion of the display area DA and may be on a front surface of the display area DA. That is, the opposite electrode 170 may be integrally formed to cover a plurality of pixels. The opposite electrode 170 may electrically contact a common power supply line 70 located in the peripheral area PA. According to some embodiments, the opposite electrode 170 may extend up to a partition wall 200.

A thin film encapsulation layer TFE may cover the whole of the display area DA, may extend to the peripheral area PA and may be arranged to cover at least a part of the peripheral area PA. The thin film encapsulation layer TFE may include a first inorganic encapsulation layer 310, a second inorganic encapsulation layer 330, and an organic encapsulation layer 320 interposed therebetween.

The first inorganic encapsulation layer 310 and the second inorganic encapsulation layer 330 may include one or more inorganic materials selected from the group consisting of aluminum oxide, titanium oxide, tantalum oxide, hafnium oxide, zinc oxide, silicon oxide, silicon nitride, and silicon oxynitride. The first inorganic encapsulation layer 310 and the second inorganic encapsulation layer 330 may have a single layer or multi-layer structure including the above-described materials. The first inorganic encapsulation layer 310 and the second inorganic encapsulation layer 330 may include the same material or different materials.

The thicknesses of the first inorganic encapsulation layer 310 may be different from each other. The thicknesses of the first inorganic encapsulation layer 310 may be different from each other. Alternatively, the thickness of the second inorganic encapsulation layer 330 may be greater than the thickness of the first inorganic encapsulation layer 310, or the thicknesses of the first inorganic encapsulation layer 310 and the second inorganic encapsulation layer 330 may be the same.

The organic encapsulation layer 320 may include a monomer-based material or a polymer-based material. The polymer-based material may include an acryl-based resin, an epoxy-based resin, polyimide, and polyethylene, and the like. According to some embodiments, the organic encapsulation layer 320 may include acrylate.

The partition wall 200 may be located in the peripheral area PA of the substrate 100. According to some embodiments, the partition wall 200 may include a portion 230 of the organic insulating layer 104, a portion 220 of the pixel-defining layer 106, and a portion 210 of the spacer 80. However, embodiments according to the present disclosure are not limited thereto. In some cases, the partition wall 200 may be formed of only the portion 230 of the organic insulating layer 104 or the portion 220 of the pixel-defining layer 106.

The partition wall 200 may be arranged to surround the display area DA and may prevent the organic encapsulation layer 320 of the thin film encapsulation layer TFE from overflowing to the outside of the substrate 100. Thus, the organic encapsulation layer 320 may be in contact with an inner surface of the partition wall 200 facing the display area DA. When the organic encapsulation layer 320 contacts an inner surface of the partition wall 200, the first inorganic encapsulation layer 310 may be located between the organic encapsulation layer 320 and the partition wall 200, and the organic encapsulation layer 320 may contact the first inorganic encapsulation layer 310. The first inorganic encapsulation layer 310 and the second inorganic encapsulation layer 330 may be arranged on the partition wall 200 and may extend to edges of the substrate 100.

FIG. 5 is a plan view schematically illustrating region A of FIG. 1.

As shown in FIG. 5, the display apparatus according to some embodiments may include the substrate 100, the inorganic insulating layer IL, the first organic insulating layer 104, the first connection wiring 420, the driving unit 30, and the feedback line 430.

Also, the substrate 100 may include the main area AE1 in which a plurality of pixels are arranged, the bending area BR bent around the bending axis from an outside of the main area AE1, and the sub area AE2 located on an opposite side to the main area AE1 with respect to the bending area BR, as described above.

The inorganic insulating layer IL may be located on the substrate 100, and the first organic insulating layer 104 may be located on the inorganic insulating layer IL, and the first connection wiring 420 may transmit a driving voltage to a plurality of pixels on the inorganic insulating layer IL, and at least a portion of the first connection wiring 420 may extend in a first direction (y-axis direction, hereinafter, the same below). The driving voltage may be the above-described driving voltage, and the first connection wiring 420 may be a wiring for transmitting the above-described driving voltage.

The driving unit 30 may serve to supply a driving voltage to the plurality of pixels through the first connection wiring 420. In addition, the driving unit 30 may adjust or control the driving voltage. The driving unit 30 may supply a compensation voltage as well as a driving voltage. The driving unit 30 may sense whether the driving voltage is normally supplied to the plurality of pixels through a feedback voltage to be described below. The driving unit 30 may adjust or control the driving voltage based on the feedback voltage. The feedback voltage that is a voltage transmitted to the driving unit through a feedback wiring, may be a value of the driving voltage sensed through the feedback wiring.

In an example, when the feedback voltage is less than the driving voltage, the driving unit 30 may adjust or control the driving voltage supplied to the plurality of pixels by supplying the compensation voltage additionally. Because the driving unit 30 adjusts or controls the driving voltage based on the feedback voltage, accurate monitoring of the feedback voltage is significant.

The feedback wiring 430 may transmit the feedback voltage between the plurality of pixels and the first connection wiring 420 to the driving unit 30 on the inorganic insulating layer IL. The feedback wiring 430 may be in direct contact with a top surface of the inorganic insulating layer IL in at least a portion of the sub area AE2. As described above, the driving unit 30 may adjust the driving voltage based on the feedback voltage transmitted through the feedback wiring 430.

In the display apparatus according to some embodiments, as will be described in the following comparative example, the feedback wiring 430 may be relatively easily separated from an organic layer due to a week adhesive force when contacting the organic layer. In this case, cracks may occur in the feedback wiring 430. When a problem occurs in the feedback wiring 430, the accuracy of the feedback voltage transmitted to the driving unit 30 may be reduced. When the driving unit 30 supplies the compensation voltage to the plurality of pixels based on the feedback voltage having low accuracy, the brightness of the plurality of pixels may be affected by the excessive driving voltage. Thus, it is significant that the feedback wiring 430 is not separated from a lower layer thereof. Because an adhesive force between an inorganic layer and a metal layer may be much stronger than the adhesive force between the organic layer and the metal layer, the inorganic layer may be located under the feedback wiring 430.

As shown in FIG. 5, the sub area AE2 may be arranged between the bending area BR and the driving unit 30. The sub area AE2 may include a first intermediate area MA1 and a second intermediate area MA2. The first intermediate area MA1 may be an area between the bending area BR and the driving unit 30, and the second intermediate area MA2 may be an area between the bending area BR and the first intermediate area MA1.

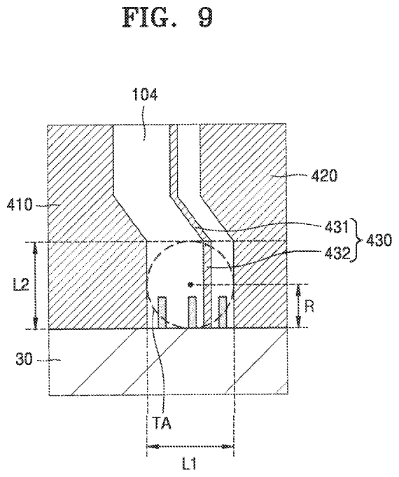

In the first intermediate area MA1, the first connection wiring 420 may be spaced apart from the second connection wiring 410 in an x-axis direction by a first length L1. The first intermediate area MA1 may extend in a y-axis direction by the first length L1, or may extend in the y-axis direction to be greater than the first length L1. A detailed description thereof will be provided with reference to FIG. 9 etc. below.

When viewed in a direction perpendicular to the substrate 100 (e.g., in a plan view0, the feedback wiring 430 may include a first portion 431 located in the first intermediate area MA1 and a second portion 432 located in the second intermediate area MA2. The first portion 431 and the second portion 432 may have the same layered structure or different layer structures. A description thereof will be provided below.

In other words, the feedback wiring 430 may include the first portion 431 located in the sub area AE2, and the second portion 432 for connecting the first portion 431 and the driving unit 30 to each other. The first part 431 may mean the rest except for the second portion 432 of the feedback wiring 430. That is, the first portion 431 may be located in all of a portion of the sub area AE2 adjacent to the bending area BR, the bending area BR, and a portion of the main area AE1 adjacent to the bending area BR.

As shown in FIG. 5, the display apparatus according to some embodiments may further include a second connection wiring 410. The second connection wiring 410 may transmit a common voltage to the main area AE1 or the plurality of pixels described above on an intermediate insulating layer. The first connection wiring 420 and the second connection wiring 410 may generally extend in the first direction, and the second connection wiring 410 may be spaced apart from the first connection wiring 420 in a second direction (x-axis direction, hereinafter, the same below) crossing the first direction when viewed in a direction perpendicular to the substrate 100 (e.g., in a plan view).

The feedback wiring 430 may be arranged between the first connection wiring 420 and the second connection wiring 410 when viewed in the direction perpendicular to the substrate 100.

As shown in FIG. 5, the first connection wiring 420 may be divided into a plurality of connection wirings in the bending area BR. Because the first connection wiring 420 needs to be bent together with the substrate 100 in the bending area BR, the first connection wiring 420 may be divided into a plurality of connection wirings that are thin to be robust to stress caused by bending. In other words, the first connection wiring 420 may extend in the first direction in the bending area BR and may be divided into a plurality of connection wirings each having a smaller width than a width of the first connection wiring 420.

Similarly, the second connection wiring 410 may be divided into a plurality of connection wirings in the bending area BR. In other words, the second connection wiring 410 may extend in the first direction in the bending area BR and may be divided into a plurality of connection wirings each having a smaller width than a width of the second connection wiring 410.

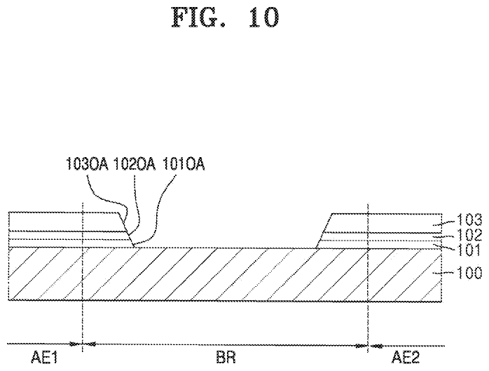

Also, the inorganic insulating layer IL having an opening corresponding to the bending area BR may be located in the bending area BR, as will be described below in FIG. 10. That is, the inorganic insulating layer IL may not exist or only a part of the inorganic insulating layer IL may be present under an organic material layer 104′ illustrated between the first connection wiring 420 and the second connection wiring 430 in the bending area BR. In this case, the organic material layer 104′ that is a layer including the same material as a material for the first organic insulating layer 104, may be a layer formed simultaneously with the first organic insulating layer 104, or separately formed after the first organic insulating layer 104 is formed.

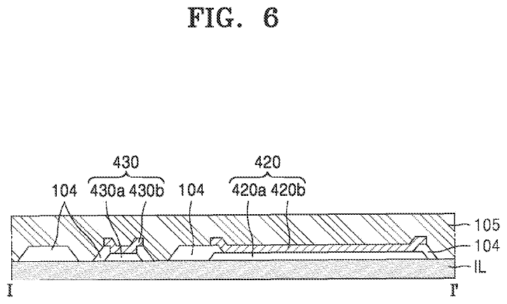

FIG. 6 is a schematic cross-sectional view of the display apparatus taken along the line I-I′ of FIG. 5 centered on a feedback wiring.

As shown in FIG. 6, the feedback wiring 430 may include a first sub feedback wiring 430a that is in direct contact with a top surface of the inorganic insulating layer IL, and a second sub feedback wiring 430b that is in direct contact with a top surface of the first sub feedback wiring 430a.

In this case, the first sub feedback wiring 430a may have the same layered structure as the first conductive layer 130 and may include the same material. In addition, the second sub feedback wiring 430b may have the same layered structure as the second conductive layer 140 and may include the same material.

In this way, when the feedback wiring 430 has a multi-layer structure including the first sub feedback wiring 430a and the second sub feedback wiring 430b, the resistance of the feedback wiring 430 may be lower than when the feedback wiring 430 has a single layer structure. Because the resistance of the feedback wiring 430 is lowered, the driving unit 30 may more accurately sense the driving voltage.

The first connection wiring 420 may include a (1-1)-th sub connection wiring 420a having the same layered structure as that of the first sub feedback wiring 430a on the interlayer insulating layer 103 and including the same material, and a (1-2)-th sub connection wiring 420b that is in direct contact with a top surface of the (1-1)-th sub connection wiring 420a, has the same layered structure as that of the second sub feedback wiring 430b and includes the same material. In this case, the (1-1)-th sub connection wiring 420a may be arranged on the inorganic insulating layer IL including the interlayer insulating layer 103 and may be in direct contact with the top surface of the inorganic insulating layer IL or the top surface of the interlayer insulating layer 103.

The first organic insulating layer 104 may cover at least a portion of edges of the first sub feedback wiring 430a. The first organic insulating layer 104 may cover at least a portion of edges of the first sub feedback wiring 430a. The first organic insulating layer 104 may include an opening for exposing at least a center part of the first sub feedback wiring 430a and may include an opening for exposing at least a center part of the (1-1)-th sub connection wiring 420a.

A top surface of the first sub feedback wiring 430a and a bottom surface of the second sub feedback wiring 430b may be in contact with each other through the opening for exposing at least a center part of the first sub feedback wiring 430a. Similarly, a top surface of the (1-1)-th sub connection wiring 420a and a bottom surface of the (1-2)-th sub connection wiring 420b may be in contact with each other through the opening for exposing at least a center part of the (1-1)-th sub connection wiring 420a.

As shown in FIG. 6, a second organic insulating layer may be arranged on the first connection wiring 420 and the feedback wiring 430 in the sub area AE2. The second organic insulating layer may be arranged on the inorganic insulating layer IL, the first inorganic insulating layer 104, the first connection wiring 420, the second connection wiring 410, and the feedback wiring 430 and may serve to planarize heights thereof.

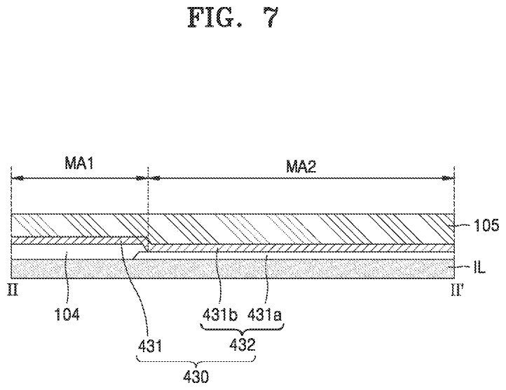

FIG. 7 is a schematic cross-sectional view of the display apparatus taken along the line II-II′ of FIG. 5 centered on a feedback wiring.

As shown in FIG. 7, the feedback wiring 430 may include the first portion 431 having a single layer structure in the sub area AE2, and the second portion 432 for connecting the first portion 431 and the driving unit 30 to each other and having a multi-layer structure.

The first portion 431 may have the same layered structure as the second sub feedback wiring 430b of FIG. 6 as a single layer structure, and may include a conductive layer including the same material as the second sub feedback wiring 430b of FIG. 6. The conductive layer of the first portion 431 may be a component corresponding to the second sub feedback wiring 430b. That is, the first portion 431 may not include a component corresponding to the first sub feedback wiring 430a.

The second portion 432 may include a first sub feedback wiring 430a and a second sub feedback wiring 430b as a multi-layer structure, as shown in FIG. 6. The second portion 432 may extend in a first direction by a second length L2 when viewed in a direction perpendicular to the substrate 100, and the second length L2 may be greater than or equal to a first length L1 that is a distance between the first connection wiring 420 and the second connection wiring 410. The second length L2 may be equal to the y-axis direction length of the first intermediate area MA1.

According to some embodiments, the second portion 432 may extend in the first direction by the second length L2 when viewed in the direction perpendicular to the substrate 100, and the second length L2 may be at least 200 μm and not more than 300 μm. In this case, the first length L1 between the first connection wiring 420 and the second connection wiring 410 may be about 200 μm. When the second length L2 is less than 200 μm, an end of the second portion 432 may be separated from a lower layer, and as such, cracks may occur in the feedback wiring 430. When the second length L2 is greater than 300 μm, cracks may not occur in the feedback wiring 430. However, the first organic insulating layer 104 may be excessively removed.

A bottom surface of the second portion 432 may be in direct contact with the top surface of the inorganic insulating layer IL or the top surface of the interlayer insulating layer 103. However, the bottom surface of the first portion 431 may be in direct contact with the top surface of the first organic insulating layer 104. That is, the first organic insulating layer 104 may be located under the first portion 431.

Because the feedback wiring 430 is divided into the first portion 431 and the second portion 432, the contact area may be limited so that the interlayer insulating layer 103, which is an inorganic layer, and the feedback wiring 430 may not excessively contact each other.

However, unlike FIG. 7, both the first portion 431 and the second portion 432 may include the first sub feedback wiring 430a and the second sub feedback line 430b of FIG. 6. In this case, both the first portion 431 and the second portion 432 may be in direct contact with the top surface of the inorganic insulating layer IL or the top surface of the interlayer insulating layer 103.

According to some embodiments, the second connection wiring 410 may have a multi-layer structure, like in the first connection wiring 420. The second connection wiring 410 may include a (2-1)-th sub connection wiring having the same layered structure as that of the first sub feedback wiring 430a on the interlayer insulating layer 103 and including the same material, and a (2-2)-th sub connection wiring that is in direct contact with a top surface of the (2-1)-th sub connection wiring, has the same layered structure as that of the second sub feedback wiring 430b and includes the same material.

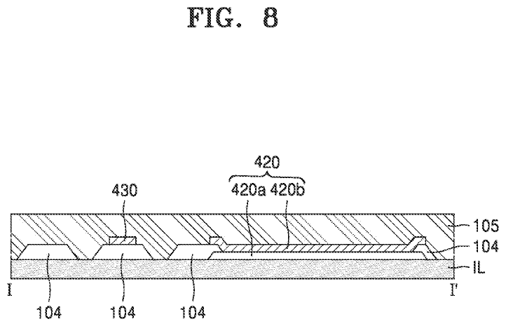

FIG. 8 is a schematic cross-sectional view schematically illustrating a portion of a display apparatus according to a comparative example, and FIG. 9 is a schematic plan view schematically illustrating a portion of a display apparatus according to a comparative example.

As shown in FIG. 8, in the display apparatus according to the comparative example, the feedback wiring 430 may have a single layer structure, and the bottom surface of the feedback wiring 430 may be in direct contact with the first organic insulating layer 104. In this case, due to a low adhesive force between the organic layer and the conductive layer, a phenomenon in which the feedback wiring 430 is separated from the first organic insulating layer 104 from the end of the feedback wiring 430 may occur.

In particularly, fine cracks may occur in the thin film encapsulation layer TFE due to stress generated when the driving unit 30 or a printed circuit board is compressed. Moisture or oxygen may penetrate into the display apparatus through fine cracks, and as a result, problems such as expansion of the organic layer may occur.

In an example, as the first inorganic insulating layer 104 expands due to moisture or oxygen, cracks may occur in the feedback wiring 43 that is in direct contact with the first organic insulating layer 104. For example, the cracks may mainly occur in the end of the feedback wiring 430 through which moisture or oxygen may easily permeate.

As shown in FIG. 9, the first organic insulating layer 104 may have a lifting area TA having a circular shape from an end. That is, moisture or oxygen permeated through cracks occurring in an end adjacent to the driving unit 30 may cause the lifting area TA from the end of the first organic insulating layer 104.

The lifting area TA may be generated between the first connection wiring 420 and the second connection wiring 410 and may occur mainly in a circular shape. The lifting area TA may have a shape of a circle with the same diameter as the first length L1. That is, when viewed in the direction perpendicular to the substrate 100 (e.g., in a plan view), a radius of the lifting area TA may be equal to the half of the first length L1.

The top surface of the inorganic insulating layer IL or the top surface of the interlayer insulating layer 103 and the bottom surface of the feedback wiring 430 may be in direct contact with each other in order to prevent the lifting area TA. Because the lifting area TA is generated in a circular shape in the first direction by the first length L1, the second portion 432 of the feedback wiring 430 having a multilayer structure so that the top surface of the inorganic insulating layer IL or the top surface of the interlayer insulating layer 103 and the bottom surface of the feedback wiring 430 are in direct contact with each other, may have a length greater than or equal to the first length Li in the first direction when viewed in the direction perpendicular to the substrate 100.

FIG. 10 is a schematic cross-sectional view of the display apparatus taken along the line III-III′ of FIG. 5 centered on an inorganic layer.

As shown in FIG. 10, an opening corresponding to the bending area BR and exposing the substrate 100 may be included in layers. When the bending area BR is bent around the bending axis, stress due to bending may be applied to layers located in the bending area BR. The layer located at a distance away from the bending axis may be more vulnerable to such stress. For example, the inorganic layer may be more vulnerable to such stress.

Thus, the layers located in the bending area BR may include an opening corresponding to the bending area BR, and as such, a display apparatus that is robust to stress by bending may be proposed.

For example, the inorganic insulating layer IL may include an opening corresponding to the bending area BR, and the interlayer insulating layer 103 may include a first opening 1010A corresponding to the bending area BR and exposing the substrate 100. In addition, each of the buffer layer 101 and the gate insulating layer may also include an opening corresponding to the bending area BR and exposing the substrate 100.

As shown in FIG. 10, the opening corresponding to the bending area BR may include a first opening 1010A, a second opening 1020A, and a third opening 1030A. When another inorganic layer is added between the buffer layer 101 and the first conductive layer 130, an opening corresponding to the added inorganic layer may be added.

The buffer layer 101 may include a first opening 1010A for exposing the substrate 100 in the bending area BR. When viewed in the direction perpendicular to the substrate 100 (e.g., in a plan view), the area of the first opening 1010A may be equal to or less than the area of the bending area BR.

The gate insulating layer may include a second opening 1020A for exposing the substrate 100 in the bending area BR. When viewed in the direction perpendicular to the substrate 100, the area of the second opening 1020A may be equal to or less than the area of the bending area BR.

The interlayer insulating layer 103 may include a third opening 1030A for exposing the substrate 100 in the bending area BR. When viewed in the direction perpendicular to the substrate 100 (e.g., in a plan view), the area of the third opening 1030A may be equal to or less than the area of the bending area BR.

The areas of the first opening 1010A, the second opening 1020A, and the third opening 1030A may be gradually increased in a direction toward the interlayer insulating layer 103 from the top surface of the substrate 100 when viewed in the direction perpendicular to the substrate 100.

That is, when viewed in the direction perpendicular to the substrate 100 (e.g., in a plan view), the first opening 1010A may be located in the second opening 1020A. Also, when viewed in the direction perpendicular to the substrate 100 (e.g., in a plan view), the second opening 1020A may be located in the third opening 1030A. The feature of the area of the first opening 1010A may reduce stress applied to the gate insulating layer when the bending area BR is bent.

An inner surface of the first opening 1010A and an inner surface of the second opening 1020A may form a continuous surface. An inner surface of the second opening 1020A and an inner surface of the third opening 1030A may form a continuous surface. As a result, inner surfaces of the first through third openings 1010A, 1020A, and 1030A may form continuous surfaces.

In addition, according to some embodiments, in some cases, the first organic insulating layer and the second organic insulating layer may also include openings corresponding to the bending area, respectively. In this case, there may be an opening included in the inorganic insulating layer and an organic material layer filled in an opening included in the organic insulating layer.

According to some embodiments of the present disclosure as described above, a display apparatus in which accurate monitoring of a driving voltage applied to a display element may be performed, can be implemented. Of course, the scope of embodiments according to the present disclosure is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display apparatus comprising:
a substrate comprising:
a main area in which a plurality of pixels are arranged;
a bending area bent around a bending axis from outside the main area; and
a sub area on an opposite side to the main area with respect to the bending area;
an interlayer insulating layer on the substrate;
a first organic insulating layer on the interlayer insulating layer;
a first connection wiring configured to transmit a driving voltage to the plurality of pixels on the interlayer insulating layer and having at least a portion extending in a first direction;
a driving unit configured to supply the driving voltage to the plurality of pixels through the first connection wiring; and
a feedback wiring configured to transmit a feedback voltage between the plurality of pixels and the first connection wiring to the driving unit on the interlayer insulating layer and being in direct contact with a top surface of the interlayer insulating layer in at least a portion of the sub area, wherein the driving unit is configured to adjust the driving voltage, based on the feedback voltage.

2. The display apparatus of claim 1, wherein the feedback wiring comprises:
a first sub feedback wiring in direct contact with a top surface of the interlayer insulating layer in at least a portion of the sub area; and
a second sub feedback wiring in direct contact with a top surface of the first sub feedback wiring.

3. The display apparatus of claim 2, wherein the first connection wiring comprises:
a (1-1)-th sub connection wiring having a same layered structure as the first sub feedback wiring on the interlayer insulating layer and including a same material as that of the first sub feedback wiring; and
a (1-2)-th sub connection wiring being in direct contact with the top surface of the (1-1)-th sub connection wiring, having a same layered structure as the second sub feedback wiring and including the same material as that of the second sub feedback wiring.

4. The display apparatus of claim 3, further comprising:
a first conductive layer between the interlayer insulating layer and the first organic insulating layer, in the main area; and
a second conductive layer on the first organic insulating layer.

5. The display apparatus of claim 4, wherein the first sub feedback wiring has a same layered structure as that of the first conductive layer and includes a same material as that of the first conductive layer, and the second sub feedback wiring has a same layered structure as that of the second conductive layer and includes a same material as that of the second conductive layer.

6. The display apparatus of claim 1, further comprising a second connection wiring configured to transmit a common voltage to the main area on the interlayer insulating layer, at least a portion of the second connection wiring being spaced apart from the first connection wiring in a second direction crossing the first direction by a first length in a plan view.

7. The display apparatus of claim 6, wherein the feedback wiring is between the first connection wiring and the second connection wiring in the plan view.

8. The display apparatus of claim 7, wherein the feedback wiring comprises:
a first portion having a single layer structure in the sub area; and
a second portion connecting the first portion and the driving unit to each other and having a multi-layer structure.

9. The display apparatus of claim 8, wherein the second portion extends in the first direction by a second length in the plan view, and the second length is greater than the first length.

10. The display apparatus of claim 8, wherein the second portion extends in the first direction by a second length in the plan view, and the second length is at least 200 micrometers (μm) and less than 300 μm.

11. The display apparatus of claim 9, wherein the second portion comprises:
a first sub feedback wiring in direct contact with a top surface of the interlayer insulating layer; and
a second sub feedback wiring in direct contact with a top surface of the first sub feedback wiring.

12. The display apparatus of claim 11, wherein the second connection wiring comprises:
a (2-1)-th sub connection wiring having a same layered structure as the first sub feedback wiring on the interlayer insulating layer and including a same material as that of the first sub feedback wiring; and
a (2-2)-th-sub connection wiring in direct contact with a top surface of the (2-1)-th sub connection wiring, having a same layered structure as the second sub feedback wiring, and including a same material as that of the second sub feedback wiring.

13. The display apparatus of claim 9, wherein the first organic insulating layer is under the first portion, and a top surface of the interlayer insulating layer is in direct contact with a bottom surface of the second portion.

14. The display apparatus of claim 1, wherein the first connection wiring is divided into a plurality of connection wirings in the bending area.

15. The display apparatus of claim 6, wherein the second connection wiring is divided into a plurality of connection wirings in the bending area.

16. The display apparatus of claim 1, further comprising a second organic insulating layer on the first connection wiring and the feedback wiring, in the sub area.

17. The display apparatus of claim 1, wherein the interlayer insulating layer comprises an opening corresponding to the bending area and exposing the substrate.
